(19) United States
(12) Patent Application Publication
(10) Pub. No.: US 2025/0301803 A1
(43) Pub. Date: Sep. 25, 2025

(54) PHOTOVOLTAIC MODULE

(71) Applicant: SHENZHEN HELLO TECH ENERGY CO., LTD, Shenzhen (CN)

(72) Inventors: Yanjun ZHU, Shenzhen (CN); Zhongwei SUN, Shenzhen (CN); Huajun YU, Shenzhen (CN); Minhuan ZHANG, Shenzhen (CN); Hongyang GU, Shenzhen (CN)

(21) Appl. No.: 19/230,148

(22) Filed: Jun. 6, 2025

Related U.S. Application Data
(63) Continuation of application No. PCT/CN2024/124260, filed on Oct. 11, 2024.

(30) Foreign Application Priority Data
May 24, 2024 (CN) 202410661847.8

(51) Int. Cl. H10F 19/85; H02S 20/23

(52) U.S. Cl. CPC H10F 19/85; H02S 20/23

(57) ABSTRACT

A photovoltaic module includes a light-transmitting panel (1), a back plate (2) disposed at a side of the light-transmitting panel (1), a photovoltaic cell layer (3) disposed between the light-transmitting panel (1) and the back plate (2), and a support plate (4) disposed between the photovoltaic cell layer (3) and the back plate (2). The light-transmitting panel (1), the back plate (2), the photovoltaic cell layer (3), and the support plate (4) are all curved structures, and have shapes adapted to each other.

### CROSS-REFERENCE TO RELATED APPLICATION

This application is a continuation application based on a PCT Application No. PCT/CN2024/124260 filed on Oct. 11, 2024, which claims priority to and benefits of Chinese patent application No. 202410661847.8, filed with China National Intellectual Property Administration on May 24, 2024, the entire contents of which are incorporated herein by reference.

### FIELD

The present disclosure relates to the field of photovoltaic batteries, and more particularly, to a photovoltaic module.

### BACKGROUND

A photovoltaic module generally includes a light-transmitting panel, a back plate, and a photovoltaic cell layer disposed between the light-transmitting panel and the back plate. For a curved photovoltaic module, a battery needs to be bent and packaged to form a curved structure. When a cell is bent and packaged, a fragmentation rate of the cell is very high, generally reaching more than 50%. In this way, a scrap rate of the battery of the curved photovoltaic module is high, which increases a production cost of the photovoltaic module.

Therefore, how to reduce the fragmentation rate of the cell of the curved photovoltaic module in a bending and packaging process has become a problem that needs to be solved urgently.

### SUMMARY

The present disclosure aims to solve one of the technical problems in the related art.

To solve the above-described technical problems, in a first aspect of the present disclosure, a photovoltaic module is provided.

According to technical solutions in the first aspect of the present disclosure, a photovoltaic module is provided. The photovoltaic module includes a light-transmitting panel, a back plate, a photovoltaic cell layer, and a support plate. The back plate is disposed at a side of the light-transmitting panel. The photovoltaic cell layer is disposed between the light-transmitting panel and the back plate. The support plate is disposed between the photovoltaic cell layer and the back plate. The light-transmitting panel, the back plate, the photovoltaic cell layer, and the support plate are all curved structures, and the light-transmitting panel, the back plate, the support plate, and the photovoltaic cell layer have shapes adapted to each other.

The photovoltaic module provided according to the technical solutions of the present disclosure includes the light-transmitting panel, the back plate, and the photovoltaic cell layer. The light-transmitting panel can transmit light. After a light passes through the light-transmitting panel and reaches a cell of the photovoltaic cell layer, electricity can be generated through a photoelectric effect. The back plate is used to protect the photovoltaic cell layer, for example, to provide waterproof protection and dustproof protection for the photovoltaic cell layer. In addition, the photovoltaic module is the curved structure, such as a photovoltaic tile structure. For a curved photovoltaic module, the light-transmitting panel is usually processed into a required curved structure in advance, and the back plate and the photovoltaic cell layer are usually processed into a flat plate structure. During assembly, the back plate and the photovoltaic cell layer need to be assembled into a flat battery module first, the flat battery module is bent into a required curved battery module, and then the curved battery module and the light-transmitting panel are assembled together to form a final photovoltaic module. The support plate is disposed between the photovoltaic cell layer and the back plate, in such a manner that when assembling the photovoltaic module, the back plate, the support plate, and the photovoltaic cell layer can be bent and processed as one module to form a required curved battery module. In this bending and deformation process, due to a presence of the support plate, a force applied to the photovoltaic cell layer can be dispersed by both the support plate and the back plate, avoiding stress concentration on the photovoltaic cell layer. That is, when an external force acts on the back plate and the support plate, the force can be better dispersed on a multi-layer structure or a thicker material, in such a manner that the force acts more evenly on the photovoltaic cell layer, avoiding the force being concentrated at one point and causing damage to the photovoltaic cell layer. In this design, both the back plate and the support plate can absorb and disperse a part of energy, which significantly reduces an impact force and a pressure transmitted to the photovoltaic cell layer itself, significantly reducing a fragmentation rate of the cell during packaging. Generally speaking, after the support plate is provided, the fragmentation rate of the cell can be reduced from 50% to about 10%.

In a possible design, the support plate has a wire routing hole. The photovoltaic module further includes a wire harness disposed between the support plate and the back plate. The wire harness includes at least one connection wire. The connection wire is electrically connected to the photovoltaic cell layer through the wire routing hole.

In this technical solution, the connection wire can be disposed between the support plate and the back plate, and connected to the cell, to supply power or transmit signals to the cell. The connection wire here can be a power wire or a signal wire. In addition, in order to facilitate connection between the connection wire and the cell, the support plate has the wire routing hole, in such a manner that the connection wire between the support plate and the back plate can pass through the wire routing hole and be connected to the cell. By disposing the connection wire between the support plate and the back plate, the photovoltaic module can avoid the connection wire protruding from two sides of the photovoltaic cell layer, compared to a conventional solution of disposing the connection wire at the photovoltaic cell layer. Thus, a width of the photovoltaic module can be increased, reducing an area of a non-power generation area at a photovoltaic edge. In this way, when a plurality of photovoltaic modules are used in combination, the number of photovoltaic modules will be reduced in a same space, reducing power generation efficiency of the photovoltaic module (that is, power generation per unit area). When the connection wire is disposed between the support plate and the back plate, the power generation efficiency of the photovoltaic module can reach more than 22%.

When the connection wire is not routed through the support plate, the power generation efficiency of the photovoltaic module is usually about 16%.

In a possible design, the photovoltaic module further includes the wire harness. The wire harness is disposed at the photovoltaic cell layer and connected to the cell. When the wire harness is disposed at the photovoltaic cell layer, a relatively large number of wires will be accumulated at the two sides of the photovoltaic cell layer. This arrangement is not conducive to the power generation efficiency, but will reduce a thickness of the photovoltaic module. Therefore, this arrangement is also possible when the power generation efficiency is not taken into consideration.

In a possible design, the support has a thickness greater than or equal to 0.1 mm and less than or equal to 0.3 mm.

The thickness of the support plate determines protection strength of the support plate to the photovoltaic cell layer and difficulty of bending an entire battery module. Therefore, the thickness of the support plate cannot be too large, otherwise, it will be difficult to bend and difficult to operate when the battery is bent and packaged. The thickness of the support plate cannot be too small, otherwise, the photovoltaic cell layer cannot be effectively supported. Taking all factors into consideration, the thickness of the support plate ranging from 0.1 to 0.3 mm can make bending difficulty and a supporting effect on the photovoltaic cell layer relatively moderate.

In a possible design, the support plate is a Polyethyleneglycolterephthalate (PET) plate or an Expandable Polyethylene (EPE) plate.

In this design, the support plate can be made of a Polyethyleneglycolterephthalate (PET) material, or a composite material of PET, or an Expandable Polyethylene (EPE, also known as pearl cotton) material. Because the support plate made of this material is light in weight and achieves the supporting effect.

In a possible design, the back plate has a thickness greater than or equal to 0.1 mm and less than or equal to 0.3 mm.

The thickness of the back plate can be set based on actual needs, but considering strength and bending packaging requirements, the thickness of the back plate can be set in a range of 0.1 mm to 0.3 mm.

In order to enhance protection to the photovoltaic cell layer, the back plate can be relatively thick. However, the back plate with a relatively large thickness is not conducive to subsequent bending packaging. Based on this, the present disclosure considers adding a layer of support plate to improve the fragmentation rate of the cell.

In a possible design, the back plate includes: a substrate; a fireproof coating disposed at a side of the substrate away from the light-transmitting panel; and/or an adhesive coating disposed at a side of the substrate close to the light-transmitting panel.

In this design, the back plate is a three-layer structure, specifically the substrate, the fireproof coating located at an outer side of the substrate (i.e., a side away from the support plate), and the adhesive coating located at an inner side of the substrate, i.e., a side close to the support plate. The fireproof coating is used to enhance fire resistance of the back plate. A material of the adhesive coating is generally similar to a material of an adhesive between the support plate and the back plate, in such a manner that the adhesive and the back plate can be adhered more firmly, enabling the support plate and the back plate to be connected more reliably.

In a possible design, the photovoltaic cell layer includes a crystalline silicon solar cell. The crystalline silicon solar cell includes at least one of a PassivatedEmitterandRearCell (PERC) solar cell, a Tunnel Oxide Passivated Contact (TOPCON) solar cell, a Cross Back Contact (XBC) solar cell, a MetalWrapThrough (MWT) solar cell, or a crystalline silicon Heterojunction with Intrinsic Thin-layer (HJT) solar cell.

In this design, the photovoltaic cell layer includes a plurality of crystalline silicon solar cells connected to each other. A type of crystalline silicon solar cell can be selected as required. For example, the crystalline silicon solar cell can be one of the PassivatedEmitterandRearCell (PERC) solar cell, the Tunnel Oxide Passivated Contact (TOPCON) solar cell, or the crystalline silicon Heterojunction with Intrinsic Thin-layer (HJT) solar cell. Alternatively, the crystalline silicon solar cell can be one of the following: the Cross Back Contact (XBC) solar cell, the MetalWrapThrough (MWT) solar cell (a high-efficiency back-contact cell with metal piercing and winding technology), or a cell with no metal busbar in a shingled structure and both a positive metal electrode and a negative metal electrode led out from a back surface of the cell.

An Interdigitated Back Contact (IBC) Crystalline Silicon Photovoltaic Cell Layer Technology is a type of photovoltaic cell layer. A Cross Back Contact (XBC) battery is a new type of high-efficiency battery derived from an IBC battery structure, which is mainly a brand-new battery based on superposition of the IBC battery structure.

In a possible design, the light-transmitting panel includes a tempered glass light-transmitting panel. The light-transmitting panel made of tempered glass has a high strength and good light transmittance, which can well meet the strength and light transmittance requirements of the light-transmitting panel of the photovoltaic module. In this way, deformation of the photovoltaic module can be avoided, ensuring a power conversion rate and a light collection effect of the photovoltaic module.

When the light-transmitting panel is tempered, full tempering can be performed to form a fully tempered light-transmitting panel. Alternatively, semi-tempering can be performed to form a semi-tempered light-transmitting panel.

In a possible design, the light-transmitting panel, the back plate, the support plate, and the photovoltaic cell layer are all multi-segment curved structures. That is, the photovoltaic module includes at least one peak and trough. The photovoltaic module with the multi-segment curved surface achieves better light collection performance.

In a possible design, the photovoltaic module further includes: a first adhesive layer disposed between the light-transmitting panel and the photovoltaic cell layer and used for adhering the light-transmitting panel to the photovoltaic cell layer; a second adhesive layer disposed between the back plate and the support plate and used for adhering the back plate to the support plate; and a third adhesive layer disposed between the photovoltaic cell layer and the support plate and used for adhering the photovoltaic cell layer to the support plate.

In this design, the photovoltaic module further includes the first adhesive layer, the second adhesive layer, and the third adhesive layer. The first adhesive layer is disposed between the light-transmitting panel and the photovoltaic cell layer and used for adhering the photovoltaic cell layer to the light-transmitting panel. The second adhesive layer is disposed between a side of the photovoltaic cell layer facing toward the support plate and the support plate and used for adhering the photovoltaic cell layer to the support plate. The third adhesive layer is disposed between the support plate and the back plate and used for adhering the support plate to the back plate. Connection between various layers of the photovoltaic module can be achieved through multiple adhesive layers, to improve connection reliability of the light-transmitting panel, the photovoltaic cell layer, the support plate, and the back plate.

In some possible designs, the first adhesive layer, the second adhesive layer, and the third adhesive layer all include any one of Ethylene-Vinyl Acetate (EVA) copolymer, Polyethylene (POE), or Polyvinyl Butyral (PVB).

In this design, the adhesive layer includes any one of Ethylene-Vinyl Acetate (EVA) copolymer, Polyethylene (POE), or Polyvinyl Butyral (PVB). This arrangement enables the adhesive layer to have a light-transmitting effect while achieving reliable adhesion. In addition, the above-described materials can also ensure that the adhesive layer has a shielding effect against ultraviolet rays.

Exemplarily, the first adhesive layer, the second adhesive layer, and the third adhesive layer each have a thickness ranging from 0.3 mm to 0.8 mm.

In some possible designs, the back plate includes a flexible plate. A surface of the flexible plate away from the photovoltaic cell layer is provided with a concave-convex structure.

In this design, a shape of the back plate can be provided based on the actual needs, for example, the back plate can be configured as a rigid plate or the back plate can be configured as a flexible plate. In addition, in order to ensure strength of the flexible plate, a concave-convex structure can be disposed at a side of the flexible plate away from the support plate. The concave-convex structure can increase a surface area, heat reflection, anti-slip, and wear resistance.

Exemplarily, the concave-convex structure can be a dot matrix, a linear structure, a mesh structure, a pyramid structure, or other random rough structures. These concave-convex structures can be quadrilaterals, hexagons, honeycombs, straight grooves, wavy lines, spiral lines, etc. These shapes are parallel or crossed, and have sizes ranging from tens of microns to several millimeters. These shapes are used to strengthen a material structure, and control light propagation to improve heat dissipation efficiency. Specially designed shapes can also be used to prevent water and dirt.

Exemplarily, the flexible plate is an aluminum foil plate. Because aluminum foil has functions of waterproofing, heat insulation, reflection, and strength support, and the aluminum foil has good ductility and can easily form and maintain a curved structure in a bending process. In this way, bending ability of the crystalline silicon solar cell can be improved and a problem of fragment of the cell can be solved. The aluminum foil plate generally has a thickness ranging from 0.1 mm to 0.3 mm. In addition, the aluminum foil itself has good fire resistance, and a photovoltaic module using the aluminum foil as a back film can meet Class A fire protection standards. The aluminum foil has high reflectivity, which can reduce solar heat radiation entering a room and reduce energy consumption of a building. The aluminum foil has water vapor barrier ability, which protects a solar cell from water vapor erosion and prolongs a life of a solar cell module. Besides, the aluminum foil plate can also replace the existing back plate with a fluoropolymer coating, enabling an entire product to be more environmentally friendly.

The support plate is an insulating plate. When the back plate is an aluminum foil plate, the support plate can also serve as an insulating layer between the aluminum foil plate and the photovoltaic cell layer.

In some possible designs, the support plate and the back plate are integrally formed as a single-piece structure, that is, the support plate and the back plate form a module, and materials thereof can be the same or different. In addition, the battery can also be supported by thickening the back plate, to reduce the fragmentation rate of the cell when the cell is bent and packaged.

Additional aspects and advantages of the present disclosure will be provided in part in the following description, or will become apparent in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a first schematic structural view of a photovoltaic module before being packaged according to an embodiment of the present disclosure.

FIG. 2 is a second schematic structural view of a photovoltaic module before being packaged according to an embodiment of the present disclosure.

FIG. 3 is a third schematic structural view of a photovoltaic module before being packaged according to an embodiment of the present disclosure.

FIG. 4 is a fourth schematic structural view of a photovoltaic module before being packaged according to an embodiment of the present disclosure.

FIG. 5 is a schematic structural view of a rigid plate according to an embodiment of the present disclosure.

FIG. 6 is a schematic structural view of a photovoltaic module according to an embodiment of the present disclosure.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure. On a basis of the embodiments of the present disclosure, all other embodiments obtained by those skilled in the art without inventive labor shall fall within the protection scope of the present disclosure.

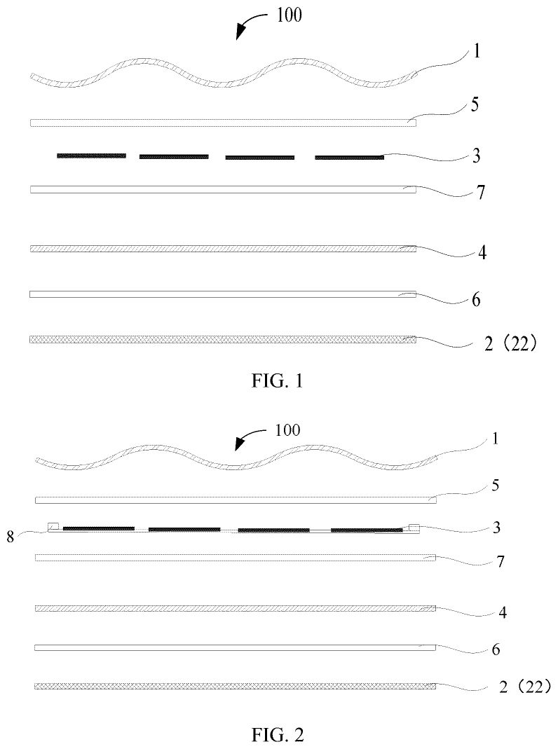

A photovoltaic module 100 according to an embodiment of the present disclosure is described below with reference to FIG. 1 to FIG. 6.

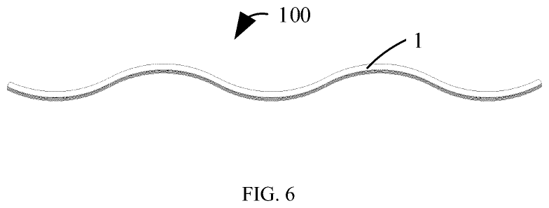

As illustrated in FIG. 1 to FIG. 6, according to an embodiment in a first aspect of the present disclosure, the photovoltaic module 100 is provided. The photovoltaic module 100 includes a light-transmitting panel 1, a back plate 2, a photovoltaic cell layer 3, and a support plate 4. The back plate 2 is disposed at a side of the light-transmitting panel 1. The photovoltaic cell layer 3 is disposed between the light-transmitting panel 1 and the back plate 2. The support plate 4 is disposed between the photovoltaic cell layer 3 and the back plate 2. As illustrated in FIG. 6, the photovoltaic module 100 is a curved structure. That is, the light-transmitting panel 1, the back plate 2, the photovoltaic cell layer 3, and the support plate 4 are all curved structures, and the light-transmitting panel 1, the back plate 2, the support plate 4, and the photovoltaic cell layer 3 have shapes adapted to each other.

The photovoltaic module 100 provided according to an embodiment of the present disclosure includes the light-transmitting panel 1, the back plate 2, and the photovoltaic cell layer 3. The light-transmitting panel 1 can transmit light. After a light passes through the light-transmitting panel 1 and reaches a cell of the photovoltaic cell layer 3, electricity can be generated through a photoelectric effect. The back plate 2 is used to protect the photovoltaic cell layer 3, for example, to provide waterproof protection and dustproof protection for the photovoltaic cell layer 3. In addition, the photovoltaic module 100 is the curved structure, such as a photovoltaic tile structure. For a curved photovoltaic module 100, the light-transmitting panel 1 is usually processed into a required curved structure in advance, and the back plate 2 and the photovoltaic cell layer 3 are usually processed into a flat structure. During assembly, the back plate 2 and the photovoltaic cell layer 3 need to be assembled into a flat battery module first, the flat battery module is bent into a required curved battery module, and then the curved battery module and the light-transmitting panel 1 are assembled together to form the photovoltaic module 100 illustrated in FIG. 6. The support plate 4 is disposed between the photovoltaic cell layer 3 and the back plate 2, in such a manner that when assembling the photovoltaic module 100, the back plate 2, the support plate 4, and the photovoltaic cell layer 3 can be bent and processed as one module to form a required curved battery module. In this bending and deformation process, due to a presence of the support plate 4, a force applied to the photovoltaic cell layer 3 can be dispersed by the support plate 4 and the back plate 2, avoiding stress concentration on the photovoltaic cell layer 3. That is, when an external force acts on the back plate 2 and the support plate 4, the force can be better dispersed on a multi-layer structure or a thicker material, in such a manner that the force acts more evenly on the photovoltaic cell layer 3, avoiding the force being concentrated at one point and causing damage to the photovoltaic cell layer 3. In this design, both the back plate 2 and the support plate 4 can absorb and disperse a part of energy, which significantly reduces an impact force and a pressure transmitted to the photovoltaic cell layer 3 itself, significantly reducing a fragmentation rate of the cell during packaging. Generally speaking, after the support plate 4 is disposed, the fragmentation rate of the cell can be reduced from 50% to about 10%.

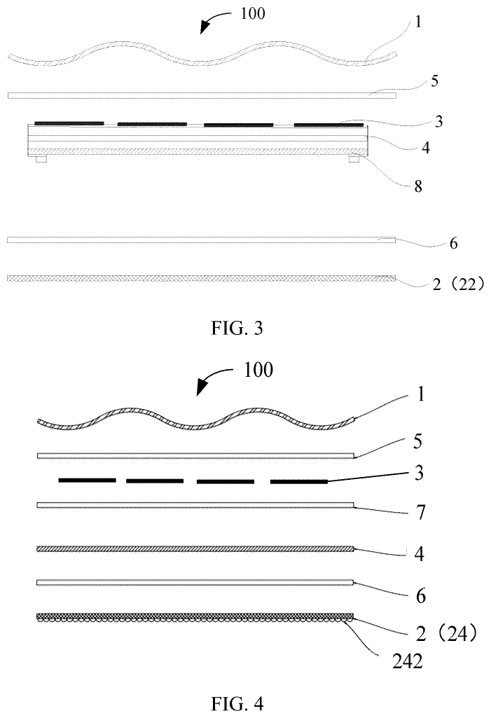

In a possible design, as illustrated in FIG. 3, the photovoltaic module 100 further includes a wire harness 8. The support plate 4 has a wire routing hole. The wire harness 8 is disposed between the support plate 4 and the back plate 2. The wire harness 8 includes at least one connection wire. The connection wire is electrically connected to the photovoltaic cell layer 3 through the wire routing hole.

In this embodiment, the connection wire can be disposed between the support plate 4 and the back plate 2, and connected to the cell, to supply power or transmit signals to the cell. The connection wire here can be a power wire or a signal wire. In addition, in order to facilitate connection between the connection wire and the cell, the support plate 4 has the wire routing hole, in such a manner that the connection wire between the support plate 4 and the back plate 2 can pass through the wire routing hole and be connected to the cell. By disposing the connection wire between the support plate 4 and the back plate 2, the photovoltaic module 100 can avoid the connection wire protruding from two sides of the photovoltaic cell layer 3 compared to a conventional solution of disposing the connection wire on the photovoltaic cell layer 3. Thus, a width of the photovoltaic module 100 can be increased, reducing an area of a non-power generation area at two sides of the photovoltaic module 100. In this way, when a plurality of photovoltaic modules 100 are used in combination, the number of photovoltaic modules 100 will be reduced in a same space, reducing power generation efficiency of the photovoltaic module 100 (that is, power generation per unit area). In the photovoltaic module 100 of an embodiment of the present disclosure, when the connection wire is disposed between the support plate 4 and the back plate 2, a width of the photovoltaic module 100 would not increase, a larger number of photovoltaic modules 100 in a same space can be provided, and the power generation efficiency of the photovoltaic module 100 can reach more than 22%. In comparison, the power generation efficiency of a photovoltaic module that is not routed through the support plate 4 is usually about 16%.

As illustrated in FIG. 3, the wire harness 8 is not stacked at the two sides of the photovoltaic cell layer 3. Before assembly, the wire harness 8 is located below the photovoltaic cell layer 3. During the assembly, the wire harness 8 is disposed between the support plate 4 and the back plate 2.

In a possible design, as illustrated in FIG. 2, the photovoltaic module 100 further includes the wire harness 8. The wire harness 8 is disposed at the photovoltaic cell layer 3 and connected to the cell. When the wire harness 8 is disposed at the photovoltaic cell layer 3, a relatively large number of wires will be accumulated at the two sides of the photovoltaic cell layer 3. This arrangement is not conducive to the power generation efficiency, but will reduce a thickness of the photovoltaic module 100. Therefore, this arrangement is also possible when the power generation efficiency is not taken into consideration.

In a possible design, the support plate 4 has a thickness greater than or equal to 0.1 mm and less than or equal to 0.3 mm.

The thickness of the support plate 4 determines protection strength of the support plate 4 to the photovoltaic cell layer 3 and difficulty of bending an entire battery module. Therefore, the thickness of the support plate 4 cannot be too large, otherwise, it will be difficult to bend and difficult to operate when the battery is bent and packaged. The thickness of the support plate 4 cannot be too small, otherwise, the photovoltaic cell layer 3 cannot be effectively supported. Taking all factors into consideration, when the thickness of the support plate 4 ranges from 0.1 to 0.3 mm, bending difficulty of the battery module is not too great, and the support plate 4 also has a good supporting effect on the photovoltaic cell layer 3.

In a possible design, the support plate 4 is a Polyethyleneglycolterephthalate (PET) plate or an Expandable Polyethylene (EPE) plate.

In this design, the support plate 4 can be made of a Polyethyleneglycolterephthalate (PET) material, or a composite material of PET, or an Expandable Polyethylene (EPE, also known as pearl cotton) material. Because the support plate 4 made of these two materials is light in weight and can ensure that the support 4 has the good supporting effect on the photovoltaic battery layer 3.

In a possible design, the back plate 2 has a thickness greater than or equal to 0.1 mm and less than or equal to 0.3 mm.

The thickness of the back plate 2 can be set based on actual needs, but considering strength and bending packaging requirements, the thickness of the back plate 2 can be set in a range of 0.1 mm to 0.3 mm.

In order to enhance protection to the photovoltaic cell layer 3, the back plate 2 can be relatively thick. However, setting the back plate 2 to be relatively thick is not conducive to subsequent bending packaging. Based on this, in the present disclosure, a solution of adding a layer of support plate 4 is selected to improve the fragmentation rate of cell in a bending and packaging process of the battery module.

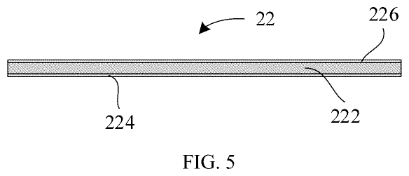

In a possible design, as illustrated in FIG. 5, the back plate 2 includes a rigid plate 22, i.e., a non-flexible plate. In an example, the rigid plate 22 includes a substrate 222 and a fireproof coating 224 disposed at a side of the substrate 222 away from the light-transmitting panel 1. In another example, the rigid plate 22 includes the substrate 222 and an adhesive coating 226 disposed at a side of the substrate 222 close to the light-transmitting panel 1.

In yet another example, the rigid plate 22 includes the substrate 222, the fireproof coating 224, and the adhesive coating 226. The fireproof coating 224 is disposed at a side of the substrate 222 away from the light-transmitting panel 1. The adhesive coating 226 is disposed at a side of the substrate 222 close to the light-transmitting panel 1. In this design, the back plate 2 is a non-flexible plate and is a three-layer structure, specifically the substrate 222, the fireproof coating 224 located at an outer side of the substrate 222 (i.e., a side away from the support plate 4), and the adhesive coating 226 located at an inner side of the substrate 222, i.e., a side close to the support plate 4. The fireproof coating 224 is used to enhance fire resistance of the back plate 2. A material of the adhesive coating 226 is generally similar to a material of an adhesive between the support plate 4 and the back plate 2, in such a manner that the adhesive and the back plate 2 can be adhered more firmly, enabling the support plate 4 and the back plate 2 to be connected more reliably.

Further, the substrate 222 has a thickness consistent with the thickness of the support plate 4. A material of the substrate 222 is identical to a material of the support plate 4.

Exemplarily, the substrate 222 is a Polyethyleneglycolterephthalate (PET) substrate.

Exemplarily, the adhesive coating 226 is a fluoropolymer coating or an Ethylene VinylAcetate (EVA) coating.

Exemplarily, the fireproof coating 224 includes a polyvinylidene difluoride (PVDF) coating and/or a Poly(vinyl formal) (PVF) coating.

In a possible design, the photovoltaic cell layer 3 includes a crystalline silicon solar cell. The crystalline silicon solar cell includes at least one of a PassivatedEmitterandRearCell (PERC) solar cell, a Tunnel Oxide Passivated Contact (TOPCON) solar cell, a Cross Back Contact (XBC) solar cell, a MetalWrapThrough (MWT) solar cell, or a crystalline silicon Heterojunction with Intrinsic Thin-layer (HJT) solar cell.

In this design, the photovoltaic cell layer 3 includes a plurality of crystalline silicon solar cells connected to each other. A type of crystalline silicon solar cell can be selected as required. For example, the crystalline silicon solar cell can be configured as one of the PassivatedEmitterandRearCell (PERC) solar cell, the Tunnel Oxide Passivated Contact (TOPCON) solar cell, or the crystalline silicon Heterojunction with Intrinsic Thin-layer (HJT) solar cell. Alternatively, the crystalline silicon solar cell can be configured as one of the following: the Cross Back Contact (XBC) solar cell, the MetalWrapThrough (MWT) solar cell (a high-efficiency back-contact cell with metal piercing and winding technology), or a cell with no metal busbar in a shingled structure and both a positive metal electrode and a negative metal electrode led out from a back surface of the cell.

An Interdigitated Back Contact (IBC) Crystalline Silicon Photovoltaic Cell Layer Technology is a type of photovoltaic cell layer. A Cross Back Contact (XBC) battery is a new type of high-efficiency battery derived from an IBC battery structure, which is mainly a brand-new battery based on superposition of the IBC battery structure.

In a possible design, the light-transmitting panel 1 includes a tempered glass light-transmitting panel. The light-transmitting panel 1 made of tempered glass has a high strength and good light transmittance, which can well meet the strength and light transmittance requirements of the light-transmitting panel 1 of the photovoltaic module 100. In this way, deformation of the photovoltaic module 100 can be avoided, ensuring a power conversion rate and a light collection effect of the photovoltaic module 100.

When the light-transmitting panel 1 is tempered, full tempering can be performed to form a fully tempered light-transmitting panel. Alternatively, semi-tempering can be performed to form a semi-tempered light-transmitting panel.

In a possible design, the light-transmitting panel 1, the back plate 2, the support plate 4, and the photovoltaic cell layer 3 are all multi-segment curved structures. That is, the photovoltaic module 100 includes at least one peak and trough. The photovoltaic module 100 with the multi-segment curved surface achieves better light collection performance.

In a possible design, as illustrated in FIG. 1 to FIG. 4, the photovoltaic module 100 further includes a first adhesive layer 5, a second adhesive layer 6, and a third adhesive layer 7. The first adhesive layer 5 is disposed between the light-transmitting panel 1 and the photovoltaic cell layer 3 and used for adhering the light-transmitting panel 1 to the photovoltaic cell layer 3. The second adhesive layer 6 is disposed between the back plate 2 and the support plate 4 and used for adhering the back plate 2 to the support plate 4. The third adhesive layer 7 is disposed between the photovoltaic cell layer 3 and the support plate 4 and used for adhering the photovoltaic cell layer 3 to the support plate 4.

In this design, the photovoltaic module 100 further includes the first adhesive layer 5, the second adhesive layer 6, and the third adhesive layer 7. The first adhesive layer 5 is disposed between the light-transmitting panel 1 and the photovoltaic cell layer 3 and used for adhering the photovoltaic cell layer 3 to the light-transmitting panel 1. The second adhesive layer 6 is disposed between a side of the photovoltaic cell layer 3 facing toward the support plate 4 and the support plate 4 and used for adhering the photovoltaic cell layer 3 to the support plate 4. The third adhesive layer 7 is disposed between the support plate 4 and the back plate 2 and used for adhering the support plate 4 to the back plate 2. The photovoltaic module 100 according to an embodiment of the present disclosure is provided with a plurality of adhesive layers, and respective layer structures of the photovoltaic module 100 can be stably connected together, improving connection reliability of the light-transmitting panel 1, the photovoltaic cell layer 3, the support plate 4, and the back plate 2.

In some possible designs, the first adhesive layer 5, the second adhesive layer 6, and the third adhesive layer 7 all include any one of Ethylene-Vinyl Acetate (EVA) copolymer, Polyethylene (POE), or Polyvinyl Butyral (PVB).

In this design, the adhesive layer includes any one of Ethylene-Vinyl Acetate (EVA) copolymer, Polyethylene (POE), or Polyvinyl Butyral (PVB). This arrangement enables the adhesive layer to have a light-transmitting effect while achieving reliable adhesion. In addition, the above-described materials can also ensure that the adhesive layer has a shielding effect against ultraviolet rays.

Exemplarily, the first adhesive layer 5, the second adhesive layer 6, and the third adhesive layer 7 each have a thickness ranging from 0.3 mm to 0.8 mm.

In some possible designs, as illustrated in FIG. 4, the back plate 2 includes a flexible plate 24. A surface of the flexible plate 24 away from the photovoltaic cell layer 3 is provided with a concave-convex structure 242.

In this design, the back plate 2 can be provided based on the actual needs, for example, the back plate 2 can be configured as the rigid plate 22 or the back plate 2 can be configured as the flexible plate 24. In addition, in order to ensure strength of the flexible plate 24, the concave-convex structure 242 can be disposed at a side of the flexible plate 24 away from the support plate 4. The concave-convex structure 242 can increase a surface area, heat reflection, anti-slip, and wear resistance.

Exemplarily, the concave-convex structure 242 can be a dot matrix structure, a linear structure, a mesh structure, a pyramid structure, or other random rough structures. These concave-convex structures can be quadrilaterals, hexagons, honeycombs, straight grooves, wavy lines, spiral lines, etc. These shapes are parallel or crossed, and have sizes ranging from tens of microns to several millimeters. These shapes are used to strengthen a material structure, and control light propagation to improve heat dissipation efficiency. Specially designed shapes can also be used to prevent water and dirt.

Exemplarily, the flexible plate includes an aluminum foil plate. Because aluminum foil has functions of waterproofing, heat insulation, reflection, and strength support, and the aluminum foil has good ductility and can easily form and maintain a curved structure in a bending process. In this way, bending ability of the crystalline silicon solar cell can be improved and a problem of fragment of the cell can be solved. The aluminum foil plate generally has a thickness ranging from 0.1 mm to 0.3 mm. In addition, the aluminum foil itself has good fire resistance, and the photovoltaic module 100 using the aluminum foil as a back film can meet Class A fire protection standards. The aluminum foil has high reflectivity, which can reduce solar heat radiation entering a room and reduce energy consumption of a building. The aluminum foil has water vapor barrier ability, which protects a solar cell from water vapor erosion and prolongs a life of a solar cell module. Besides, the aluminum foil plate can also replace the existing back plate 2 with a fluoropolymer coating, enabling the entire photovoltaic module 100 to be more environmentally friendly.

The support plate 4 is an insulating plate. When the back plate 2 is an aluminum foil plate, the support plate 4 can also serve as an insulating layer between the aluminum foil plate and the photovoltaic cell layer 3.

In some possible designs, the support plate 4 and the back plate 2 are integrally formed as a single-piece structure, that is, the support plate 4 and the back plate 2 form a module, and the material of the support plate 4 and the material of the back plate 2 can be the same or different. In addition, the cell can also be supported by thickening the back plate 2 to reduce the fragmentation rate of the cell when the cell is bent and packaged.

The photovoltaic module 100 in the present disclosure is further introduced below by taking a curved photovoltaic product as an example.

Curved photovoltaic products, due to their unique design and flexibility, are widely used in a variety of different occasions, including roof power generation tiles, car roofs, and special-shaped buildings.

The curved photovoltaic products can be directly integrated into building structures as roofing materials, forming photovoltaic tiles. This integrated design is not only aesthetically pleasing, but also effectively utilizes roof space for power generation, which reduces dependence on traditional roofing materials.

The curved photovoltaic products are also applied in the car roofs to provide additional power for vehicles. This application not only helps to improve energy efficiency, but also provides charging for electric vehicles or hybrid vehicles, which increases endurance of a vehicle. A curved design can be flexibly customized based on a shape of a car roof to maximize efficiency of photovoltaic power generation. For buildings in unique or irregular shapes, the curved photovoltaic products provide ideal solutions. The curved photovoltaic products can be customized based on specific shape and design requirements of a building and seamlessly integrated into a surface of the building, which combines aesthetics with functionality. The customized curved photovoltaic products not only enhance the energy efficiency of the building, but also enhance modernity and technological sophistication of the building.

A biggest challenge in applying the crystalline silicon solar cell to a curved product is fragment of the cell. The crystalline silicon solar cell is typically kept flat during manufacturing, to accommodate traditional mounting and application. However, in the curved photovoltaic product, the cell needs to adapt to the curved structure, which requires the cell to feature a certain bending ability. Ensuring that the bending ability of the cell matches curvature of the product without compromising performance of the cell and structural integrity is a technical challenge. Packaging and protection of the curved photovoltaic product need to take into account a curved characteristic of the product. Packaging materials need to be able to adapt to a curved shape and provide sufficient protection to prevent damage to the cell caused by processing forces and environmental factors (such as water, dust, ultraviolet rays, etc.). A processing technology of the curved photovoltaic product needs to be specially designed to ensure that the cell is not damaged during manufacturing, which involves stress control when bending the cell, temperature control during packaging, and stability of an overall structure.

Building regulations usually have clear provisions for safety performance of building materials, including fire resistance standards. These regulations are followed not only for legal compliance, but also for ensuring safety and reliability of the building. Secondly, use of fireproof building materials is an important means to protect people's lives and property. The fireproof building materials can effectively slow down spread of fire and buy valuable time for personnel evacuation and fire rescue, reducing casualties and property losses caused by the fire. By using building materials that meet the fire resistance standards, higher safety guarantee can be provided for buildings, reducing fire risks, and ensuring safety of the people's lives and property.

Due to absorption and conduction of solar radiation by the roofing materials, an indoor temperature rises, which affects comfort of living and working, and increases energy consumption of cooling equipment such as air conditioners. High temperatures will reduce power of solar power generation. Roof insulation is an important part of building energy conservation, which is of great significance for improving the comfort of living and working, saving energy, and reducing operating costs of buildings. Roof insulation is not only related to energy efficiency and environmental protection of the buildings, but also directly affects the comfort and economic costs of users.

Taking into account the above-described aspects, this embodiment provides a structure of a curved power generation tile, which is a composite curved photovoltaic power generation product formed by stacking multiple layers of materials in sequence.

As illustrated in FIG. 1, a first surface of the curved power generation tile is light-transmitting glass, and a glass has a shape of a curved surface. The Light passes through the glass and reaches the cell to generate electricity through the photoelectric effect. A second surface of the product is the back plate 2 with a fireproof function. The photovoltaic cell layer 3 formed by the cell is disposed between the back plate 2 and the light-transmitting glass. The support plate 4 is also disposed between the photovoltaic cell layer 3 and the back plate 2.

When the photovoltaic cell layer 3 is bent, the support plate 4 and the back plate 2 jointly protect the cell of the photovoltaic cell layer 3 to prevent the cell from cracking.

The light-transmitting glass is rigid curved glass. Materials of all other layers of the curved power generation tile are generally flat before assembly, but possess flexibility for bending. During the assembly, the materials of the all other layers of the curved power generation tile can be bent and fitted along a shape of the rigid glass.

The cell is the crystalline silicon solar cell. The crystalline silicon solar cell includes a cell with PassivatedEmitterandRearCell (PERC), Tunnel Oxide Passivated Contact (TOPCON), Cross Back Contact (XBC), MetalWrapThrough (MWT), and crystalline silicon Heterojunction with Intrinsic Thin-layer (HJT) routes.

The back plate 2, the light-transmitting glass, the support plate 4, and the photovoltaic cell layer 3 are connected by adhesive films and are manufactured into the photovoltaic module 100 by a vacuum lamination process. A main function of these adhesive films is to protect the cell and prolong a service life of the photovoltaic module 100. Common materials include an ethylene-vinyl acetate copolymer (EVA) adhesive film, a polyolefin elastomer (POE) adhesive film, a co-extruded POE (EPE) adhesive film, and other types of adhesive films, such as a Polyvinyl Butyral (PVB) adhesive film.

The support plate 4 has a function of supporting and protecting the cell, and an intermediate interlayer formed between the support plate 4 and the back plate 2 can be used to arrange wires and reduce space occupied by the wires in the photovoltaic cell layer 3. In this way, an area of a non-power generation area at an edge of the photovoltaic module 100 is reduced, and power generation per unit area (i.e., photoelectric conversion efficiency of the module) is improved. The support plate 4 has a thickness ranging from 0.13 mm to 0.3 mm. Common materials include a Polyethyleneglycolterephthalate (PET) material, a co-extruded POE (EPE) material, etc.

In a specific embodiment, as illustrated in FIG. 1 to FIG. 3, the back plate 2 is made of a flexible material bent to a shape of glass. The back plate 2 is coated with the fireproof coating 224 at a surface of the back plate 2, which features functions of fireproofing, water vapor barrier, and strength support. The back plate 2 has a thickness generally ranging from 0.1 mm to 0.3 mm. The back plate 2 is composed of at least three layers. A middle layer is mainly made of a Polyethyleneglycolterephthalate (PET) material. At the packaging side is the adhesive coating 226, which is generally a fluoropolymer film or ethylene-vinyl acetate copolymer (EVA) adhesive film. An outer surface is coated with the fireproof coating 224, such as a polyvinylidene difluoride (PVDF) coating/a Poly(vinyl formal) (PVF) coating, which provides excellent weather resistance and flame retardancy.

In another specific embodiment, as illustrated in FIG. 4, the back plate 2 is reflective aluminum foil, which is made of the flexible material bent into the shape of glass, and the concave-convex structure 242 is disposed at a surface of the aluminum foil, which features the functions of waterproofing, heat insulation, reflection, and strength support. At this time, the support plate 4 has the function of supporting and protecting the cell, and also serves as an insulation layer between the aluminum foil and the cell. The support plate 4 does not need a fluoropolymer coating, which is more environmentally friendly. With the thickness ranging from 0.1 mm to 0.3 mm, the support plate 4 is thinner than the conventional outermost photovoltaic a back plate 2, and common materials include Polyethyleneglycolterephthalate (PET) material, a co-extruded POE (EPE) material, etc.

Based on an embodiment of the present disclosure, a back of the cell is supported and protected by two layers of materials, namely, the support plate 4 and the back plate 2, which solves the problem of fragment of the crystalline silicon solar cell when the cell is bent and packaged. A structure with the back plate 2 alone has a fragmentation rate of over 50%. After the support plate 4 is added, the fragmentation rate decreases to about 10%

When the photovoltaic product needs to be packaged, modules formed by the photovoltaic cell layer 3, the support plate 4, and the back plate 2 need to be bent into a same curved shape as the light-transmitting panel 1. In this bending and deformation process, due to the existence of the support plate 4, the force applied to the photovoltaic cell layer 3 can be dispersed by the support plate 4 and the back plate 2, avoiding the stress concentration on the photovoltaic cell layer 3. That is, when the external force acts on the back plate 2 and the support plate 4, the multi-layer structure or the thicker material can better disperse the force, in such a manner that the force acts more evenly on the photovoltaic cell layer 3, avoiding the force being concentrated at one point and causing damage to the photovoltaic cell layer 3. Both the back plate 2 and the support plate 4 can absorb and disperse a part of the energy, which significantly reduces the impact force and the pressure transmitted to the photovoltaic cell layer 3 itself, reducing the fragmentation rate of the cell during packaging.

Further, the support plate 4 also enables a thickness on a backside of the photovoltaic cell layer 3 to be relatively thick. In this way, during the assembly and use of the photovoltaic module 100, the back plate 2 and the support plate 4 can jointly protect the photovoltaic cell layer 3, preventing the external force from damaging the photovoltaic cell layer 3, and prolonging the service life of the battery. For example, in shock protection, thick or multi-layered materials can provide more cushioning space to absorb energy generated during drops or impacts.

An interlayer between the support plate 4 and the back plate 2 is used to arrange lead-out wires (as illustrated in FIG. 2), replacing an arrangement of the wires at the photovoltaic cell layer (as illustrated in FIG. 2). In this way, the area of the non-power generation area at the edge of the module is reduced, enabling power generation efficiency of the curved power generation tile (that is, the power generation per unit area) to reach more than 22%. When the wires are not routed through the support plate 4, the power generation efficiency of the curved power generation tile is usually about 16%.

In another exemplary embodiment of the present disclosure, the back plate 2 can meet Class A fireproof requirements for the building materials.

According to an embodiment of the present application, a roof (not illustrated in the figures) is also provided, including the photovoltaic module 100 according to any of the above-described embodiments.

The roof provided in the present disclosure includes the photovoltaic module 100 according to any of the above-described embodiments, and therefore has all the beneficial effects of the photovoltaic module 100.

According to an embodiment of the present disclosure, a building (not illustrated in the figures) is also provided, including the photovoltaic module 100 according to any of the above-described embodiments or the roof according to any of the above-described embodiments.

The building provided in the present disclosure includes the photovoltaic module 100 according to any of the above-described embodiments or the roof according to any of the above-described embodiments, and therefore has all the beneficial effects of the photovoltaic module 100 or the roof.

In the description of the present disclosure, reference throughout this specification to “an embodiment,” “some embodiments,” “schematic embodiment,” “example,” “a specific example,” or “some examples” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics can be combined in any suitable manner in one or more embodiments or examples.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A photovoltaic module, comprising:
a light-transmitting panel;
a back plate disposed at a side of the light-transmitting panel;
a photovoltaic cell layer disposed between the light-transmitting panel and the back plate; and
a support plate disposed between the photovoltaic cell layer and the back plate;
wherein the light-transmitting panel, the back plate, the photovoltaic cell layer, and the support plate are all curved structures, and the light-transmitting panel, the back plate, the support plate, and the photovoltaic cell layer have shapes adapted to each other.

2. The photovoltaic module according to claim 1, wherein:
the support plate has a wire routing hole; and
the photovoltaic module further comprises a wire harness disposed between the support plate and the back plate, the wire harness comprising at least one connection wire, and the connection wire being electrically connected to the photovoltaic cell layer through the wire routing hole.

3. The photovoltaic module according to claim 1, wherein the support plate has a thickness greater than or equal to 0.1 mm and less than or equal to 0.3 mm.

4. The photovoltaic module according to claim 1, the support plate is a Polyethyleneglycolterephthalate (PET) plate or an Expandable Polyethylene (EPE) plate.

5. The photovoltaic module according to claim 1, wherein the back plate has a thickness greater than or equal to 0.1 mm and less than or equal to 0.3 mm.

6. The photovoltaic module according to claim 1, wherein the back plate comprises:
a substrate;
a fireproof coating disposed at a side of the substrate away from the light-transmitting panel; and/or
an adhesive coating disposed at a side of the substrate close to the light-transmitting panel.

7. The photovoltaic module according to claim 6, wherein:
the substrate has a thickness consistent with a thickness of the support plate; and
a material of the substrate is identical to a material of the support plate.

8. The photovoltaic module according to claim 6, wherein:
the adhesive coating is a fluoropolymer coating or an Ethylene VinylAcetate (EVA) coating; and
the fireproof coating is a polyvinylidene difluoride coating and/or a Poly (vinyl formal) coating.

9. The photovoltaic module according to claim 1, wherein the back plate comprises a flexible plate, a surface of the flexible plate away from the photovoltaic cell layer being provided with a concave-convex structure.

10. The photovoltaic module according to claim 9, wherein the flexible plate comprises an aluminum foil plate.

11. The photovoltaic module according to claim 1, wherein:
the photovoltaic cell layer comprises a crystalline silicon solar cell comprising at least one of a PassivatedEmitterandRearCell (PERC) solar cell, a Tunnel Oxide Passivated Contact (TOPCON) solar cell, a Cross Back Contact (XBC) solar cell, a MetalWrapThrough (MWT) solar cell, or a crystalline silicon Heterojunction with Intrinsic Thin-layer (HJT) solar cell; and/or
the light-transmitting panel comprises a tempered glass light-transmitting panel.

12. The photovoltaic module according to claim 1, further comprising:
a first adhesive layer disposed between the light-transmitting panel and the photovoltaic cell layer and used for adhering the light-transmitting panel to the photovoltaic cell layer;
a second adhesive layer disposed between the back plate and the support plate and used for adhering the back plate to the support plate; and
a third adhesive layer disposed between the photovoltaic cell layer and the support plate and used for adhering the photovoltaic cell layer to the support plate.

13. The photovoltaic module according to claim 1, wherein the photovoltaic cell layer comprises a plurality of crystalline silicon solar cells connected to each other.

14. The photovoltaic module according to claim 1, wherein the light-transmitting panel, the back plate, the support plate, and the photovoltaic cell layer are all multi-segment curved structures.

15. The photovoltaic module according to claim 12, wherein the first adhesive layer, the second adhesive layer, and the third adhesive layer all comprise any one of Ethylene-Vinyl Acetate (EVA) copolymer, Polyethylene (POE), or Polyvinyl Butyral (PVB).

16. The photovoltaic module according to claim 12, wherein the first adhesive layer, the second adhesive layer, and the third adhesive layer each have a thickness ranging from 0.3 mm to 0.8 mm.

17. The photovoltaic module according to claim 10, wherein the aluminum foil plate has a thickness ranging from 0.1 mm to 0.3 mm.

18. The photovoltaic module according to claim 1, wherein the support plate and the back plate are integrally formed as a single-piece structure.

19. A roof, comprising a photovoltaic module, wherein the photovoltaic module comprises:
a light-transmitting panel;
a back plate disposed at a side of the light-transmitting panel;
a photovoltaic cell layer disposed between the light-transmitting panel and the back plate; and
a support plate disposed between the photovoltaic cell layer and the back plate;
wherein the light-transmitting panel, the back plate, the photovoltaic cell layer, and the support plate are all curved structures, and the light-transmitting panel, the back plate, the support plate, and the photovoltaic cell layer have shapes adapted to each other.

20. A building, comprising a roof, the roof comprising a photovoltaic module, wherein the photovoltaic module comprises:
a light-transmitting panel;
a back plate disposed at a side of the light-transmitting panel;
a photovoltaic cell layer disposed between the light-transmitting panel and the back plate; and
a support plate disposed between the photovoltaic cell layer and the back plate;
wherein the light-transmitting panel, the back plate, the photovoltaic cell layer, and the support plate are all curved structures, and the light-transmitting panel, the back plate, the support plate, and the photovoltaic cell layer have shapes adapted to each other.
